(19) United States
(12) Patent Application Publication
(10) Pub. No.: US 2022/0308386 A1
(43) Pub. Date: Sep. 29, 2022

(54) LIGHT SHIELDING MATERIAL, PATTERNING METHOD THEREOF, AND DISPLAY PANEL

(71) Applicant: TLC CHINA STAR OPTOELECTRONICS TECHNOLOGY CO., LTD., Shenzhen (CN)

(72) Inventor: Xiaodan LIN, Shenzhen (CN)

(73) Assignee: TLC CHINA STAR OPTOELECTRONICS TECHNOLOGY CO., LTD., Shenzhen (CN)

(21) Appl. No.: 16/757,388

(22) PCT Filed: Mar. 24, 2020
(86) PCT No.: PCT/CN2020/080813

§ 371 Date: Apr. 18, 2020

(30) Foreign Application Priority Data
Mar. 5, 2020 (CN) 202010146989.2

(51) Int. Cl. G02F 1/1335; C08K 3/22; C08K 5/05; C08L 33/08; C08L 83/04

(52) U.S. Cl. CPC G02F 1/133512; C08K 3/22; C08K 5/05; C08L 33/08; C08L 83/04; G09F 9/33

(57) ABSTRACT

The present disclosure provides a light shielding material, a patterning method thereof, and a display panel. The light shielding material includes a light shielding composition and a transparent composition, the light shielding composition includes Ti₇O₄ and a dispersant, and the transparent composition includes a first compound, a photoactive compound, and a first solvent. Through dispersing Ti₇O₄ into the transparent composition, the light shielding material can be obtained in the present disclosure, which has an excellent light shielding effect, thereby preventing technical problems of scraps and scratches of the light shielding material caused by printing a black oil on the light shielding material using copper screen printing in current technology.

### FIELD OF INVENTION

The present disclosure relates to the field of display technologies, and more particularly, to a light shielding material, a patterning method thereof, and a display panel.

### BACKGROUND OF INVENTION

As living standards improve, mini light-emitting diode (mini LED) display panels have become more widely used. The display panels comprise black matrices used to shield non-light-emitting devices.

In current technology, technical problems of scraps and scratches of a light shielding material easily occur when forming a black matrix by printing a black oil on the light shielding material using copper screen printing.

Therefore, it is necessary to provide a light shielding material, a patterning method thereof, and a display panel to solve the above technical problems.

Technical problem: the present disclosure provides a light shielding material, a patterning method thereof, and a display panel to solve the technical problems of scraps and scratches of the light shielding material when forming a black matrix by printing a black oil on the light shielding material using copper screen printing.

### SUMMARY OF INVENTION

To solve the above problems, an embodiment of the present disclosure provides technical solutions as follows:

A light shielding material, comprising a light shielding composition and a transparent composition;

wherein the light shielding composition comprises Ti₇O₄ and a dispersant; and

the transparent composition comprises a first compound, a photoactive compound, and a first solvent.

In the light shielding material of the present disclosure, the dispersant comprises 2-methylpentanol or polypropylene compounds.

In the light shielding material of the present disclosure, the first compound comprises polyacrylic acid or siloxane.

In the light shielding material of the present disclosure, the first solvent comprises propylene glycol methyl ether acetate, propylene glycol methyl ether, methyl 3-methoxypropionate, or diethylene glycol methyl ethyl ether.

In the light shielding material of the present disclosure, the transparent composition further comprises an additive, and the additive comprises silane functional groups.

In the light shielding material of the present disclosure, a mass fraction of the additive in the light shielding material is less than 2%.

In the light shielding material of the present disclosure, a mass fraction of Ti₇O₄ in the light shielding material ranges from 3% to 5%;

a mass fraction of the first compound in the light shielding material ranges from 10% to 15%;

a mass fraction of the photoactive compound in the light shielding material ranges from 2% to 5%; and

a mass fraction of the first solvent in the light shielding material ranges from 70% to 75%.

A patterning method of a light shielding material, comprising following steps:

exposing the light shielding material using a mask to allow a photoactive compound to undergo a reaction;

etching the light shielding material using a developer; and

performing a thermal curing reaction on the light shielding material to manufacture the light shielding material having a predetermined pattern;

wherein the light shielding material comprises a light shielding composition and a transparent composition, the light shielding composition comprises Ti₇O₄ and a dispersant, and the transparent composition comprises a first compound, the photoactive compound, and a first solvent.

In the patterning method of the light shielding material of the present disclosure, the dispersant comprises 2-methylpentanol or polypropylene compounds.

In the patterning method of the light shielding material of the present disclosure, the first compound comprises polyacrylic acid or siloxane.

In the patterning method of the light shielding material of the present disclosure, the first solvent comprises propylene glycol methyl ether acetate, propylene glycol methyl ether, methyl 3-methoxypropionate, or diethylene glycol methyl ethyl ether.

In the patterning method of the light shielding material of the present disclosure, the transparent composition further comprises an additive, and the additive comprises silane functional groups.

In the patterning method of the light shielding material of the present disclosure, a mass fraction of the additive in the light shielding material is less than 2%.

In the patterning method of the light shielding material of the present disclosure, a mass fraction of Ti₇O₄ in the light shielding material ranges from 3% to 5%;

a mass fraction of the first compound in the light shielding material ranges from 10% to 15%;

a mass fraction of the photoactive compound in the light shielding material ranges from 2% to 5%; and

a mass fraction of the first solvent in the light shielding material ranges from 70% to 75%.

In the patterning method of the light shielding material of the present disclosure, a reaction formula of a partial reaction of the photoactive compound is:

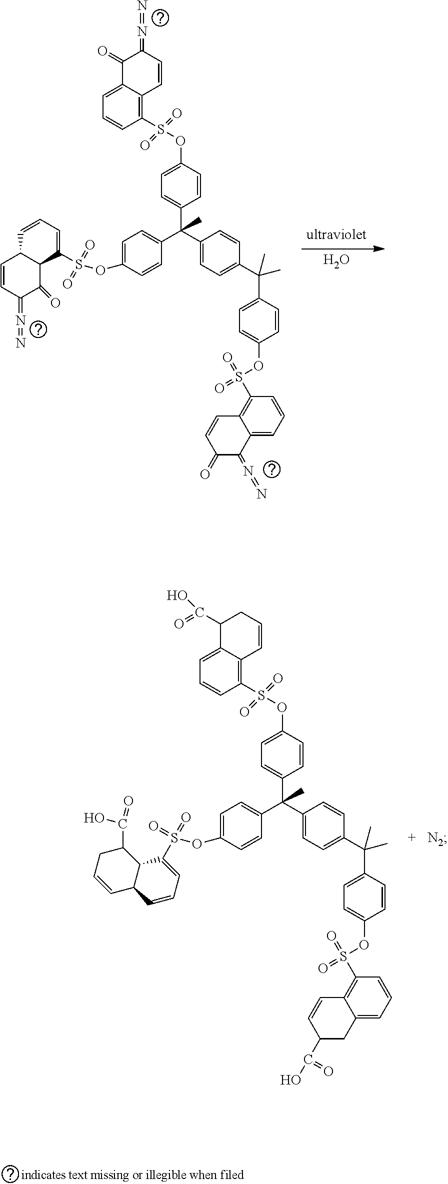

a reaction formula of etching the light shielding material is:

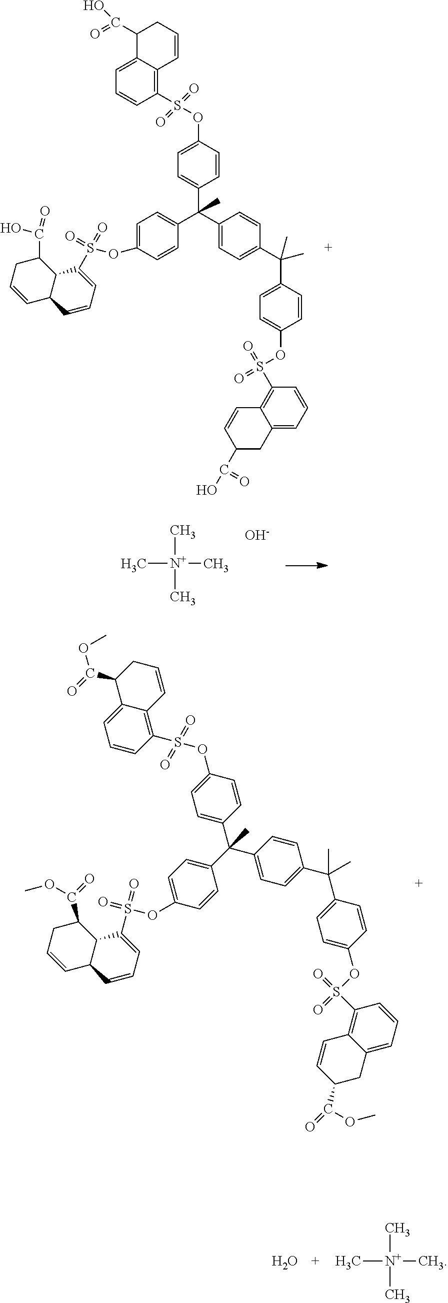

In the patterning method of the light shielding material of the present disclosure, the developer is an alkaline developer having tetramethylammonium hydroxide.

In the patterning method of the light shielding material of the present disclosure, a temperature of the thermal curing reaction ranges from 200° C. to 250° C., and a reaction time thereof ranges from 40 minutes to 50 minutes.

A display panel, wherein a light shielding area of the display panel comprises a light shielding material;

the light shielding material comprises a light shielding composition and a transparent composition;

wherein the light shielding composition comprises Ti₇O₄ and a dispersant; and

the transparent composition comprises a first compound, a photoactive compound, and a first solvent.

In the display panel of the present disclosure, the transparent composition further comprises an additive, and the additive comprises silane functional groups.

In the display panel of the present disclosure, a mass fraction of Ti₇O₄ in the light shielding material ranges from 3% to 5%;

a mass fraction of the first compound in the light shielding material ranges from 10% to 15%;

a mass fraction of the photoactive compound in the light shielding material ranges from 2% to 5%; and

a mass fraction of the first solvent in the light shielding material ranges from 70% to 75%.

Beneficial effect: the present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

### DESCRIPTION OF DRAWINGS

FIG. 1 is a flowchart of a patterning method of a light shielding material according to an embodiment of the present disclosure.

### DETAILED DESCRIPTION OF PREFERRED EMBODIMENTS

The present disclosure provides a light shielding material, a patterning method thereof, and a display panel. In order to make the purpose, technical solutions, and effects of the present disclosure clearer and more definite, the following further describes the present disclosure in detail with reference to the drawings and embodiments. It should be understood that the specific embodiments described herein are only used to explain the disclosure, and are not used to limit the disclosure.

The present disclosure provides a light shielding material which comprises a light shielding composition and a transparent composition.

The light shielding composition comprises Ti₇O₄ and a dispersant.

The transparent composition comprises a first compound, a photoactive compound, and a first solvent.

The present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

Specific embodiments are used to describe technical solutions of the present disclosure.

The present disclosure provides a light shielding material which comprises a light shielding composition and a transparent composition.

The light shielding composition comprises Ti₇O₄ and a dispersant.

The transparent composition comprises a first compound, a photoactive compound, and a first solvent.

Wherein, the photoactive compound and the first compound are used for patterning the light shielding material.

In the embodiment, Ti₇O₄ is a black colorant of the light shielding material.

In the embodiment, the dispersant comprises 2-methylpentanol or polypropylene compounds.

In the embodiment, the polypropylene compounds can be polyacrylic acid. When the first compound is polyacrylic acid, the dispersant is also polyacrylic acid, which will not produce unnecessary by-products due to the dispersant and simplify compositions.

In the embodiment, the first compound comprises polyacrylic acid or siloxane. The first compound is a host material of the light shielding material. A structural formula of polyacrylic acid is as follows:

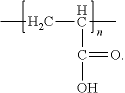

Siloxane is a polymer, and a structure thereof comprises:

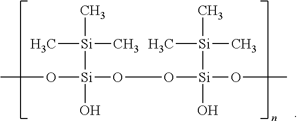

In the embodiment, the photoactive compound is a photoacid complex and is manufactured by reacting diazonaphthoquinone and a heat stabilizer. Diazonaphthoquinone is a photosensitizer, and the heat stabilizer is a complex, which comprises phenyl series. The photoactive compound, diazonaphthoquinone, and the heat stabilizer all can be obtained from industry. A structure of the photoactive compound comprises:

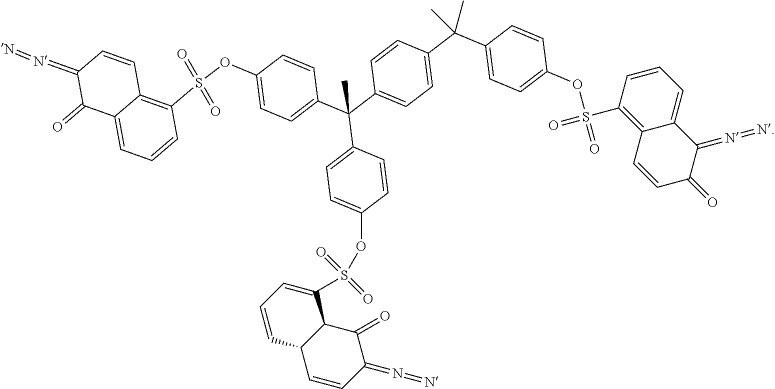

When the photoactive compound is exposed to ultraviolet, it will produce carboxylic acid structures, which will undergo an acid-base reaction under an effect of a developer, and the light shielding material exposed to the ultraviolet will be developed to form a predetermined pattern.

In the embodiment, the first solvent can dissolve the first compound, the photoactive compound, and the dispersant.

In the embodiment, the first solvent comprises propylene glycol methyl ether acetate, propylene glycol methyl ether, methyl 3-methoxypropionate, or diethylene glycol methyl ethyl ether.

In the embodiment, the transparent composition further comprises an additive. The additive can increase leveling of the light shielding material, and can improve adhesion and viscosity of the light shielding material, which can reduce pollution of the light shielding material to other parts of the display panel. The additive comprises silane functional groups. The silane functional groups include silane alkoxy groups, which have dual characteristics of lipophilic and hydrophilic. A glass substrate has an inorganic interface, while the light shielding material has an organic interface. The silane functional groups can bond the inorganic interface and the organic interface together, which improves a surface tension of the light shielding material on the glass substrate and allows the light shielding material to uniformly attach to the glass.

In the embodiment, a mass fraction of the additive in the light shielding material is less than 2%. The mass fraction of the additive in the light shielding material is lesser, and does not impose sudden change in overall performance of the light shielding material, and meanwhile can increase the leveling of the light shielding material, and improve adhesion and viscosity of the light shielding material.

In the embodiment, a mass fraction of Ti₇O₄ in the light shielding material ranges from 3% to 5%. A mass fraction of the first compound in the light shielding material ranges from 10% to 15%. A mass fraction of the photoactive compound in the light shielding material ranges from 2% to 5%. A mass fraction of the first solvent in the light shielding material ranges from 70% to 75%.

The embodiment of the present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

The present disclosure further provides a patterning method of a light shielding material, which comprises following steps:

S10: mixing and filtrating Ti₇O₄ and a dispersant to obtain a first mixture;

S20: mixing and filtrating a first compound, a photoactive compound, and a first solvent to obtain a second mixture;

S30: mixing and filtrating the first mixture and the second mixture to obtain the light shielding material.

The present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

Specific embodiments are used to describe technical solutions of the present disclosure.

The present disclosure provides a patterning method of a light shielding material, which comprises following steps:

S10: mixing and filtrating Ti₇O₄ and a dispersant to obtain a first mixture.

In the embodiment, Ti₇O₄ is a black colorant of the light shielding material.

In the embodiment, the dispersant comprises 2-methylpentanol or polypropylene compounds.

In the embodiment, the polypropylene compounds can be polyacrylic acid. When the first compound is polyacrylic acid, the dispersant is also polyacrylic acid, which will not produce unnecessary by-products due to the dispersant and simplify compositions.

In the embodiment, the step S10 comprises:

S11: mixing Ti₇O₄ and the dispersant uniformly according to a first ratio.

In the embodiment, the first ratio is a process parameter adapted to production, and may be selected according to specific conditions and effects to be achieved.

S12: filtrating the well mixed solution of the step S11 in a filter element to obtain the first mixture.

S20: mixing and filtrating a first compound, a photoactive compound, and a first solvent to obtain a second mixture.

In the embodiment, the first compound comprises polyacrylic acid or siloxane. The first compound is a host material of the light shielding material. A structural formula of polyacrylic acid is as follows:

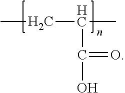

Siloxane is a polymer, and a structure thereof comprises:

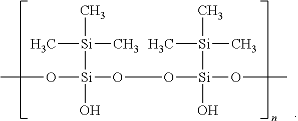

In the embodiment, the photoactive compound is a photoacid complex and is manufactured by reacting diazonaphthoquinone and a heat stabilizer. Diazonaphthoquinone is a photosensitizer, and the heat stabilizer is a complex, which comprises phenyl series. The photoactive compound, diazonaphthoquinone, and the heat stabilizer all can be obtained from industry. A structure of the photoactive compound comprises:

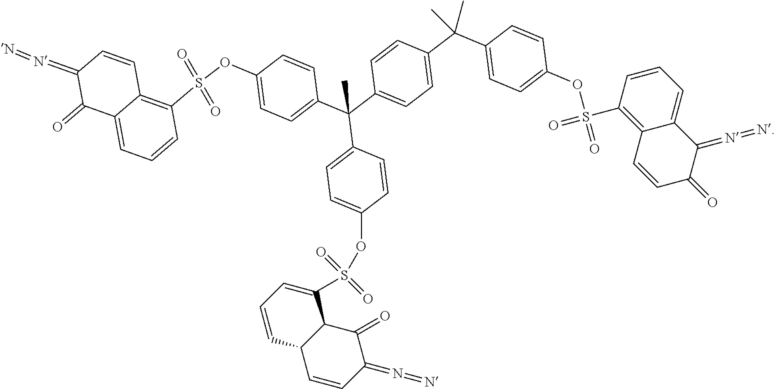

In the embodiment, the first solvent can dissolve the first compound, the photoactive compound, and the dispersant.

In the embodiment, the first solvent comprises propylene glycol methyl ether acetate, propylene glycol methyl ether, methyl 3-methoxypropionate, or diethylene glycol methyl ethyl ether.

In the embodiment, a mass fraction of Ti₇O₄ in the light shielding material ranges from 3% to 5%. A mass fraction of the first compound in the light shielding material ranges from 10% to 15%. A mass fraction of the photoactive compound in the light shielding material ranges from 2% to 5%. a mass fraction of the first solvent in the light shielding material ranges from 70% to 75%.

In the embodiment, the step S20 is to mix and filtrate the first compound, the photoactive compound, the first solvent, and an additive to obtain the second mixture.

Wherein, the additive comprises silane functional groups.

In the embodiment, the transparent composition further comprises an additive. The additive can increase leveling of the light shielding material, and can improve adhesion and viscosity of the light shielding material, which can reduce pollution of the light shielding material to other parts of the display panel. The additive comprises silane functional groups. The silane functional groups include silane alkoxy groups, which have dual characteristics of lipophilic and hydrophilic. A glass substrate has an inorganic interface, while the light shielding material has an organic interface. The silane functional groups can bond the inorganic interface and the organic interface together, which improves a surface tension of the light shielding material on the glass substrate and allows the light shielding material to uniformly attach to the glass.

In the embodiment, a mass fraction of the additive in the light shielding material is less than 2%. The mass fraction of the additive in the light shielding material is lesser, and does not impose sudden change in overall performance of the light shielding material, and meanwhile can increase the leveling of the light shielding material, and improve adhesion and viscosity of the light shielding material.

S30: mixing and filtrating the first mixture and the second mixture to obtain the light shielding material.

In the embodiment, the step S30 comprises:

S31: mixing and stirring the first mixture and the second mixture according to a second ratio.

In the embodiment, the second ratio is a process parameter adapted to production, and may be selected according to specific conditions and effects to be achieved.

In the embodiment, the mass fraction of the additive in the light shielding material, the mass fraction of Ti₇O₄ in the light shielding material, the mass fraction of the first compound in the light shielding material, the mass fraction of the photoactive compound in the light shielding material, and the mass fraction of the first solvent in the light shielding material can be converted into a mass ratio of the first mixture to the second mixture by the second ratio.

S32: filtrating the well mixed solution of the step S31 in a filter element to obtain the light shielding material.

In the embodiment, the photoactive compound in the light shielding material can produce carboxylic acid structures under exposure of ultraviolet, and can undergo an acid-base reaction under an effect of a developer, and the light shielding material exposed to the ultraviolet will be developed to form a predetermined pattern. The developer used is an alkaline developer having tetramethylammonium hydroxide.

In the embodiment, the photoactive compound (PAC) which is not exposed to the ultraviolet light will undergo a thermal curing reaction to react with the first compound, which finally forms the light shielding material. Taking polyacrylic acid as an example, sulfur-oxygen double bonds in the PAC are opened to react with polyacrylic acid and then forms a polymer, which is the light shielding material.

In the embodiment, a temperature of the thermal curing reaction ranges from 200° C. to 250° C., and a reaction time thereof ranges from 40 minutes to 50 minutes. Wherein, a better thermal curing effect can be obtained when the reaction temperature is at 230° C.

The embodiment of the present disclosure obtains the light shielding material by dispersing Ti₇O₄ into the transparent composition. The light shielding material can be patterned by exposing to ultraviolet. The light shielding material has an excellent light shielding effect, and meanwhile prevents the technical problems of scraps and scratches of the light shielding material caused by printing a black oil on the light shielding material using copper screen printing in current technology.

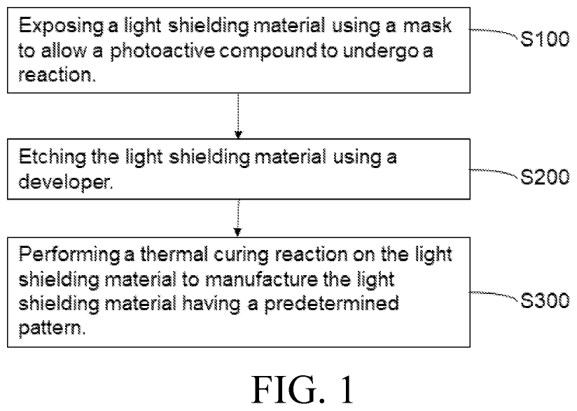

Referring to FIG. 1, an embodiment of the present disclosure further provides a patterning method of the above light shielding material, which comprises following steps:

S100: exposing the light shielding material using a mask to allow a photoactive compound to undergo a reaction;

S200: etching the light shielding material using a developer; and

S300: performing a thermal curing reaction on the light shielding material to manufacture the light shielding material having a predetermined pattern.

The present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

Specific embodiments are used to describe technical solutions of the present disclosure.

The present disclosure provides a patterning method of the above light shielding material, which comprises following steps:

S100: exposing the light shielding material using a mask to allow a photoactive compound to undergo a reaction.

In the embodiment, the photoactive compound can produce carboxylic acid structures under exposure of ultraviolet, and can undergo an acid-base reaction under an effect of a developer, and the light shielding material exposed to the ultraviolet will be developed to form a predetermined pattern.

In the embodiment, a reaction formula of a partial reaction of the photoactive compound of the step S100 is:

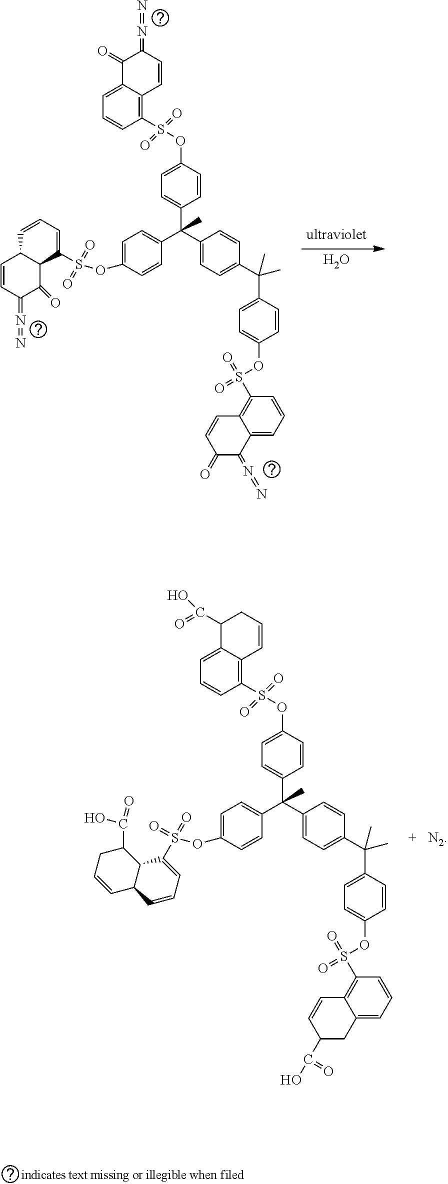

S200: etching the light shielding material using a developer.

In the embodiment, the developer used is an alkaline developer having tetramethylammonium hydroxide.

In the embodiment, a reaction formula of etching the light shielding material of the step S100 is:

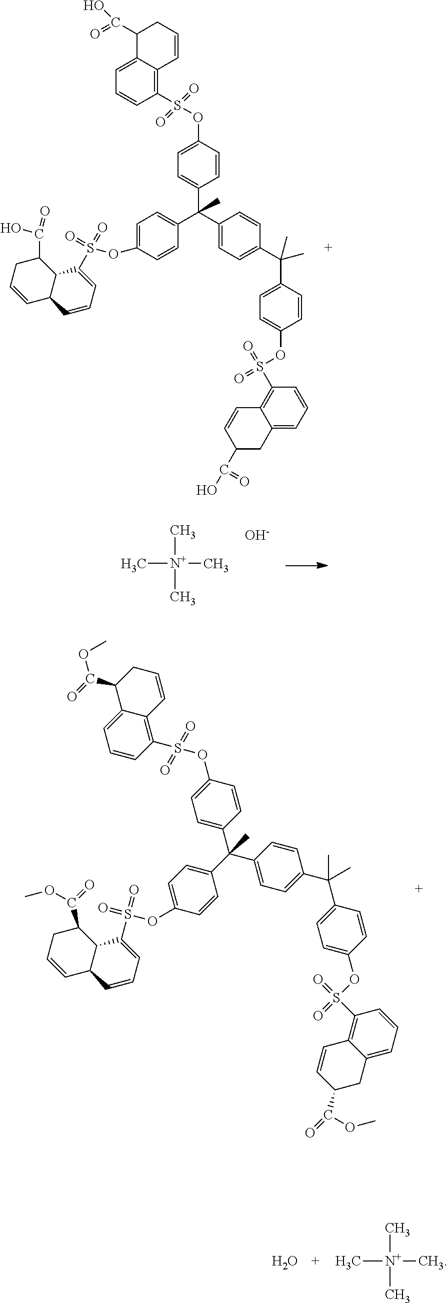

S300: performing a thermal curing reaction on the light shielding material to manufacture the light shielding material having a predetermined pattern.

In the embodiment, the photoactive compound (PAC) which is not exposed to the ultraviolet light will undergo a thermal curing reaction to react with the first compound, which finally forms the light shielding material. Taking polyacrylic acid as an example, sulfur-oxygen double bonds in the PAC are opened to react with polyacrylic acid and then forms a polymer, which is the light shielding material. A formula of the thermal curing reaction is as follows:

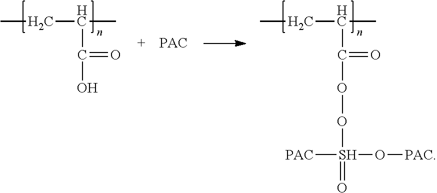

In the embodiment, a temperature of the thermal curing reaction ranges from 200° C. to 250° C., and a reaction time thereof ranges from 40 minutes to 50 minutes. Wherein, a better thermal curing effect can be obtained when the reaction temperature is at 230° C. The obtained light shielding material has flexibility, and can better relieve stress when the display panel is squeezed.

The embodiment of the present disclosure uses a mask to have the light shielding material undergo a patterning process of exposure and development, and forms a predetermined pattern, which can accurately and rapidly shield light on a light shielding area of the display panel and improve light shielding effect and display effect of the display panel.

The present disclosure further provides a display panel. A light shielding area of the display panel comprises any one of the above light shielding materials.

The present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

Specific embodiments are used to describe technical solutions of the present disclosure.

The present disclosure provides a display panel which comprises a substrate and a mini LED light board.

The mini LED light board comprises any one of the light shielding materials described in the embodiments of the present disclosure.

In the embodiment, the mini LED light board comprises a first substrate and a plurality of colored mini LEDs disposed on the first substrate.

In the embodiment, the colored mini LEDs comprise red light mini LEDs, green light mini LEDs, or blue light mini LEDs.

In the embodiment, a light shielding area of any one of the colored mini LEDs is provided with any one of the light shielding materials according to the embodiments of the present disclosure.

In the embodiment, a light shielding area between two adjacent colored mini LEDs is provided with any one of the light shielding materials according to the embodiments of the present disclosure.

In the embodiment, the display panel can also be a liquid crystal display panel which comprises a substrate, a liquid crystal layer, and a color filter layer. A light shielding area of the color filter layer comprises any one of the light shielding materials according to the embodiments of the present disclosure.

In the embodiment, the light shielding material may be a light shielding material that has been subjected to any one of the patterning processes of the light shielding materials in the present disclosure, which forms a predetermined pattern that can accurately and rapidly shield light and improve visual effect of the display panel.

The light shielding material in the embodiment can be referred to any one of the light shielding materials according to the embodiments of the present disclosure, which is not repeated herein.

The embodiment of the present disclosure obtains the light shielding material by dispersing Ti₇O₄ into the transparent composition. The light shielding area of the display panel comprises the light shielding material. The light shielding material has an excellent light shielding effect, and meanwhile prevents the technical problems of scraps and scratches of the light shielding material caused by printing a black oil on the light shielding material using copper screen printing in current technology.

In summary, the present disclosure provides a light shielding material, a patterning method thereof, and a display panel. The light shielding material includes a light shielding composition and a transparent composition, the light shielding composition includes Ti₇O₄ and a dispersant, and the transparent composition includes a first compound, the photoactive compound, and a first solvent. The present disclosure obtains the light shielding material by dispersing Ti₇O₄ into the transparent composition. The light shielding material has an excellent light shielding effect, and meanwhile prevents the technical problems of scraps and scratches of the light shielding material caused by printing a black oil on the light shielding material using copper screen printing in current technology.

It can be understood that for a person of ordinary skill in the art, equivalent replacements or changes can be made according to the technical solution of the present disclosure and its inventive concept, and all these changes or replacements should fall within the protection scope of the claims attached to the present disclosure.

What is claimed is:

1. A light shielding material, comprising a light shielding composition and a transparent composition;
wherein the light shielding composition comprises Ti₇O₄ and a dispersant; and
the transparent composition comprises a first compound, a photoactive compound, and a first solvent.

2. The light shielding material according to claim 1, wherein the dispersant comprises 2-methylpentanol or polypropylene compounds.

3. The light shielding material according to claim 1, wherein the first compound comprises polyacrylic acid or siloxane.

4. The light shielding material according to claim 1, wherein the first solvent comprises propylene glycol methyl ether acetate, propylene glycol methyl ether, methyl 3-methoxypropionate, or diethylene glycol methyl ethyl ether.

5. The light shielding material according to claim 1, wherein the transparent composition further comprises an additive, and the additive comprises silane functional groups.

6. The light shielding material according to claim 5, wherein a mass fraction of the additive in the light shielding material is less than 2%.

7. The light shielding material according to claim 1, wherein a mass fraction of Ti₇O₄ in the light shielding material ranges from 3% to 5%;
a mass fraction of the first compound in the light shielding material ranges from 10% to 15%;
a mass fraction of the photoactive compound in the light shielding material ranges from 2% to 5%; and
a mass fraction of the first solvent in the light shielding material ranges from 70% to 75%.

8. A patterning method of a light shielding material, comprising following steps:
exposing the light shielding material using a mask to allow a photoactive compound to undergo a reaction;
etching the light shielding material using a developer; and
performing a thermal curing reaction on the light shielding material to manufacture the light shielding material having a predetermined pattern;
wherein the light shielding material comprises a light shielding composition and a transparent composition, the light shielding composition comprises Ti₇O₄ and a dispersant, and the transparent composition comprises a first compound, the photoactive compound, and a first solvent.

9. The patterning method of the light shielding material according to claim 8, wherein the dispersant comprises 2-methylpentanol or polypropylene compounds.

10. The patterning method of the light shielding material according to claim 8, wherein the first compound comprises polyacrylic acid or siloxane.

11. The patterning method of the light shielding material according to claim 8, wherein the first solvent comprises propylene glycol methyl ether acetate, propylene glycol methyl ether, methyl 3-methoxypropionate, or diethylene glycol methyl ethyl ether.

12. The patterning method of the light shielding material according to claim 8, wherein the transparent composition further comprises an additive, and the additive comprises silane functional groups.

13. The patterning method of the light shielding material according to claim 12, wherein a mass fraction of the additive in the light shielding material is less than 2%.

14. The patterning method of the light shielding material according to claim 8, wherein a mass fraction of Ti₇O₄ in the light shielding material ranges from 3% to 5%;
a mass fraction of the first compound in the light shielding material ranges from 10% to 15%;
a mass fraction of the photoactive compound in the light shielding material ranges from 2% to 5%; and
a mass fraction of the first solvent in the light shielding material ranges from 70% to 75%.

15. The patterning method of the light shielding material according to claim 8, wherein a reaction formula of a partial reaction of the photoactive compound is: 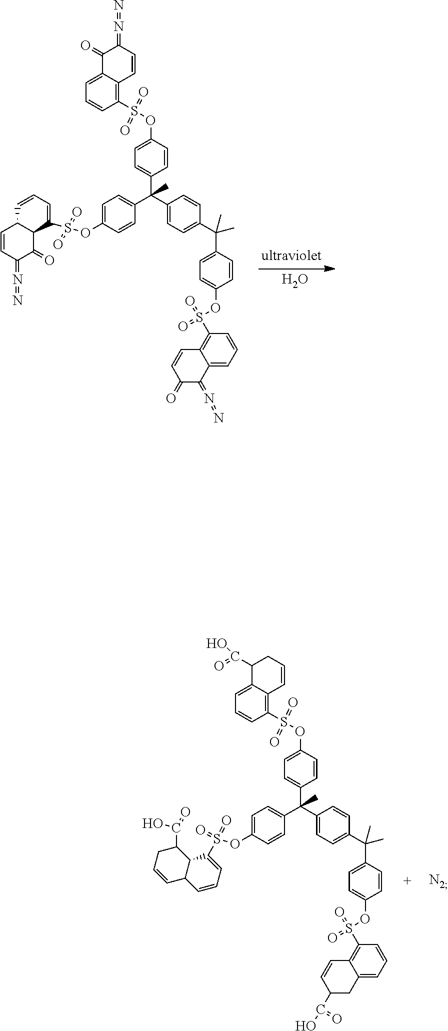
a reaction formula of etching the light shielding material is:

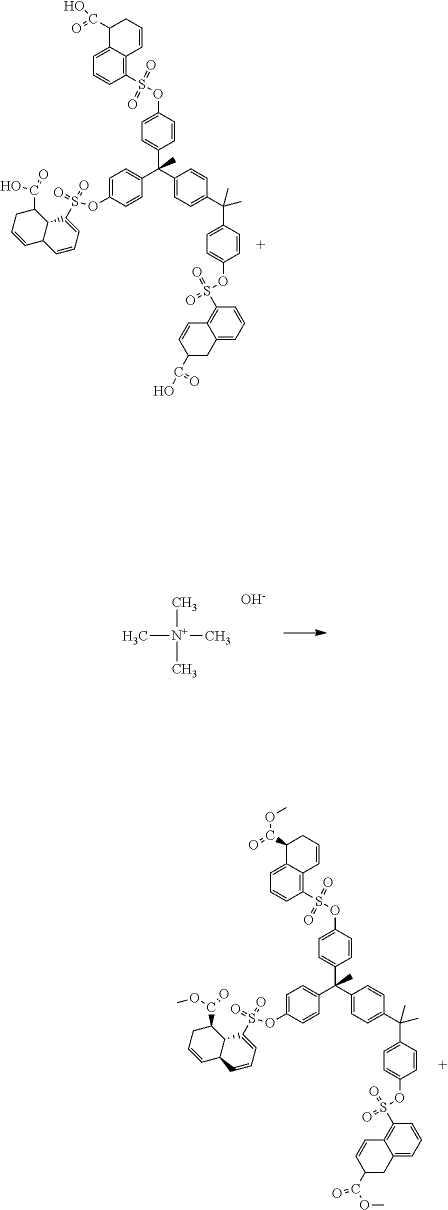

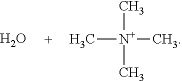

16. The patterning method of the light shielding material according to claim 8, wherein the developer is an alkaline developer having tetramethylammonium hydroxide.

17. The patterning method of the light shielding material according to claim 8, wherein a temperature of the thermal curing reaction ranges from 200° C. to 250° C., and a reaction time thereof ranges from 40 minutes to 50 minutes.

18. A display panel, wherein a light shielding area of the display panel comprises a light shielding material;
the light shielding material comprises a light shielding composition and a transparent composition;
the light shielding composition comprises Ti₇O₄ and a dispersant; and
the transparent composition comprises a first compound, a photoactive compound, and a first solvent.

19. The display panel according to claim 18, wherein the transparent composition further comprises an additive, and the additive comprises silane functional groups.

20. The display panel according to claim 18, wherein a mass fraction of Ti₇O₄ in the light shielding material ranges from 3% to 5%;
a mass fraction of the first compound in the light shielding material ranges from 10% to 15%;
a mass fraction of the photoactive compound in the light shielding material ranges from 2% to 5%; and
a mass fraction of the first solvent in the light shielding material ranges from 70% to 75%.
